(19) United States
(12) Patent Application Publication
(10) Pub. No.: US 2013/0087780 A1
(43) Pub. Date: Apr. 11, 2013

(54) GROUP III NITRIDE SEMICONDUCTOR LIGHT EMITTING DIODE

(71) Applicant: YU-ZUNG CHIOU, TAINAN CITY (TW)

(72) Inventor: YU-ZUNG CHIOU, TAINAN CITY (TW)

(73) Assignee: SOUTHERN TAIWAN UNIVERSITY OF TECHNOLOGY, TAINAN CITY (TW)

(21) Appl. No.: 13/267,921

(22) Filed: Oct. 7, 2011

(51) Int. Cl. H01L 33/02; H01L 33/62

(52) U.S. Cl. 257/43; 257/99; 257/76; 257/77; 257/E33.066; 257/E33.023; 257/E33.019

(57) ABSTRACT

A group III nitride semiconductor light emitting diode is revealed. A layered structure composed of group III nitrides is formed on the substrate through epitaxy growth of a hexagonal wurtzite crystal structure. The layered structure includes a n-type semiconductor layer, a light emitting layer on the n-type semiconductor layer, and a p-type semiconductor layer on the light emitting layer. A first electrode metal pad is formed on the p-type semiconductor layer and a second electrode metal pad on the n-type semiconductor layer. A direction from the first electrode metal pad to the second electrode metal pad is the same with that of C-axis [0001] of the hexagonal wurtzite crystal structure so as to speed up the movement of electron-hole and improve the combination efficiency of electron-hole by the electric field along the direction of C-axis [0001] in the hexagonal wurtzite crystal structure.

### BACKGROUND OF THE INVENTION

1. Field of the Invention

The present invention relates to a group III nitride semiconductor light emitting diode (LED), especially to a light emitting diode having a substrate and a layered structure formed on the substrate, wherein the direction from the first electrode metal pad to the second electrode metal pad is the same with that of C-axis [0001] of a hexagonal wurtzite crystal structure formed on the light emitting diode, so as to result in a polarization direction parallel to directions of the first and second electrode metal pads to increase the electron-hole combination efficiency, and further to enhance the output power of the light emitting diode.

2. Description of Related Art

In recent years, nitride-based semiconductor light emitting diodes (LEDs) can be made with small components in an environmental manner to reduce mercury pollutions and show a high luminous efficiency, a long lifetime or the like as advantages, so they has become one of most emerging optoelectronic semiconductor materials. In addition, the wavelength of group III nitride semiconductor light emitting diode almost covers the wavelength range of visible light, making the conventional LED become a kind of the light emitting diode material with a great potential for practical usages or applications.

In general, group III nitride has a hexagonal wurtzite crystal structure in a steady state. The hexagonal wurtzite crystal structure is composed of two interactive mixed hexagonal close-packed (HCP) structure as shown in FIG. 4. With epitaxial growth along the direction of C-axis [0001] of the hexagonal wurtzite crystal structure, the spontaneous polarization effect in the absence of external electric field is induced by the dipole moment due to non-coincidence of the positive and negative charge centers within unit cell. In addition to the spontaneous polarization effect, the piezoelectric polarization effect is induced by the heterogeneous epitaxial growth process due to the lattice constant mismatch between the epitaxial layer and the substrate. Thus, the crystal structure is deformed by the epitaxial mismatch so as to induce the piezoelectric field effect, which further causes the piezoelectric polarization effect.

In summary, both spontaneous polarization effect and piezoelectric polarization effect exist in the hexagonal wurtzite crystal structure of group III nitrides. In addition, the conventional direction from a p-type electrode to a n-type electrode in a semiconductor light emitting diode is perpendicular to the direction of C-axis [0001] of the hexagonal wurtzite crystal structure, thus it leads to a a separation of the electron-hole wave functions in the multiple quantum well (MQW). As a result of a poor electron-hole overlap, the light emitting efficiency of multiple quantum well as well as the output power of light emitting diode would be reduced. Furthermore, the semiconductor light emitting diode suffers from a efficiency droop at higher current densities, resulting in internal quantum efficiency could decay as the current increases, thus strongly restricted by the higher power applications such as illuminating.

### SUMMARY OF THE INVENTION

Therefore it is a primary object of the present invention to provide a group III nitride semiconductor light emitting diode having a substrate and a layered structure formed on the substrate, wherein the direction from the first electrode metal pad to the second electrode metal pad is the same with that of C-axis [0001] of a hexagonal wurtzite crystal structure formed on the light emitting diode. As a result, the electric field induced by both spontaneous polarization and piezoelectric polarization is parallel to the direction from the first electrode metal pad to the second electrode metal pad, so as to increase the probability of the electron-hole overlap. Thus, for the light emitting diode device, the threshold voltage is dropped and the output power is increased.

In order to achieve the above object, a group III nitride semiconductor light emitting diode includes a substrate for epitaxy growth of a hexagonal wurtzite crystal structure, and a layered structure formed on the substrate. The layered structure comprises an n-type semiconductor layer, a light emitting layer on the n-type semiconductor layer, a p-type semiconductor layer on the light emitting layer, wherein the n-type semiconductor layer, the light emitting layer and the p-type semiconductor layer are composed of group III nitrides, a first electrode metal pad formed on the p-type semiconductor layer and a second electrode metal pad on the n-type semiconductor layer, wherein a direction from the first electrode metal pad to the second electrode metal pad is the same with the direction of C-axis [0001] of the hexagonal wurtzite crystal structure.

Accordingly, the electric field induced by both spontaneous polarization and piezoelectric polarization exists in the hexagonal wurtzite crystal structure of group III nitride semiconductor light emitting diode along the C-axis [0001] thereof. A direction of the electric field is parallel to that from the first electrode metal pad to the second electrode metal pad, resulting in the movement of electron-hole can be speeded up through the electric field. The combination efficiency of electron-hole is increasing, thus the threshold voltage is dropped, and the output power is improved.

Moreover, the layered structure is formed through epitaxy growth of the hexagonal wurtzite crystal structure having a M-plane or a A-plane on the substrate, resulting in the reduction of spontaneous polarization effect. Thus electrons and holes can be more evenly distributed in the light emitting layer. The external quantum efficiency droop can be effectively reduced at higher current densities.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a cross sectional view of an embodiment of a semiconductor light emitting diode according to the present invention;

FIG. 2 is a top view of the cross section of a light emitting layer according to the present invention;

FIG. 3 is schematic drawing showing a unit cell of an embodiment of a hexagonal wurtzite crystal structure according to the present invention;

FIG. 4 is a schematic drawing showing a conventional hexagonal wurtzite crystal structure.

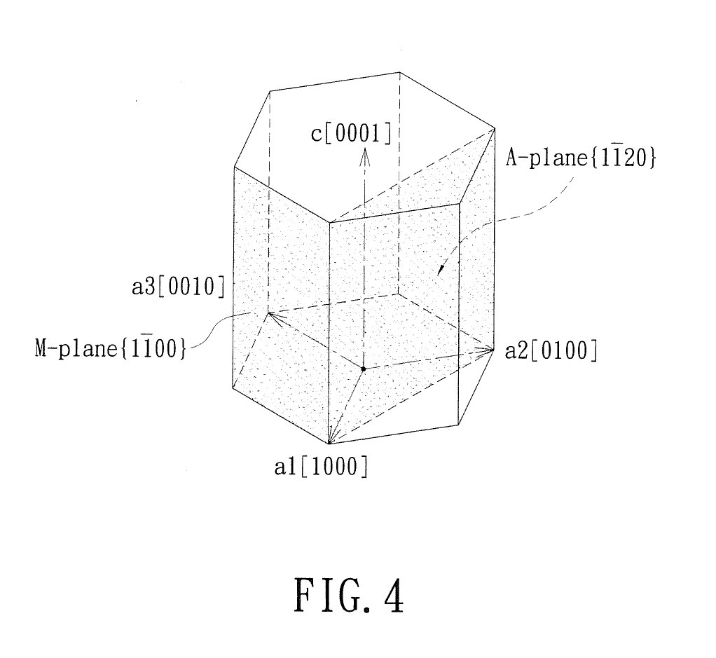

### DETAILED DESCRIPTION OF THE PREFERRED EMBODIMENT

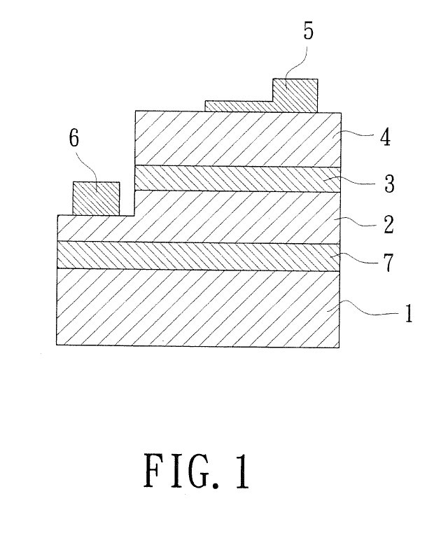

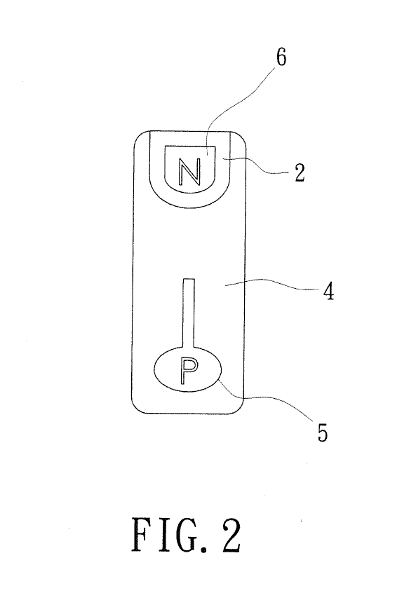

Referring to FIGS. 1, 2, and 3, a preferred embodiment of the group III nitride semiconductor light emitting diode in accordance with the present invention is revealed, which mainly comprising a substrate 1 for epitaxy growth of a hexagonal wurtzite crystal structure and a layered structure formed on the substrate 1. The layered structure is formed successively with a n-type semiconductor layer 2, a light emitting layer 3 and a p-type semiconductor layer 4. Still, a first electrode metal pad 5 is formed on the p-type semiconductor layer 4 and a second electrode metal pad 6 on the n-type semiconductor layer 2. The n-type semiconductor layer 2, the light emitting layer 3 and the p-type semiconductor layer 4 are all composed of group III nitrides, and a direction from the first electrode metal pad 5 to the second electrode metal pad 6 is the same with the direction of C-axis [0001 ] of the hexagonal wurtzite crystal structure. The first electrode metal pad 5 is a p-type electrode, and the second electrode metal pad 6 is a n-type electrode. In addition, the buffer layer 7 is epitaxially grown between the substrate 1 and the n-type semiconductor layer 2 in order to diminish the crystal lattices mismatch between the layers.

In the preferred embodiment of the present invention, the substrate 1 is formed of sapphire, SiC, Si, GaN, AN, or ZnO. The group III nitride is selected from at least one of AlN, GaN, InN, AlGaN, ALInN, InGaN, and AlInGaN.

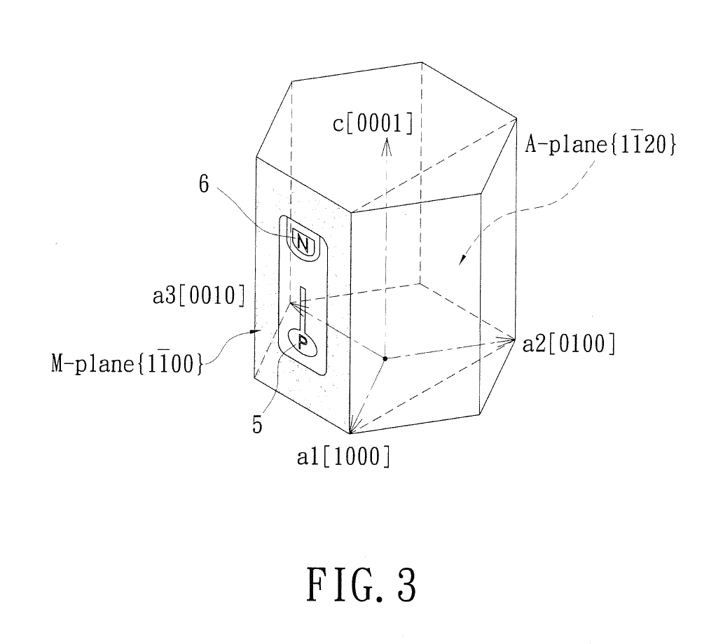

Referring to FIG. 3, the layered structure can be formed through epitaxy growth of the hexagonal wurtzite crystal structure having an M-plane or A-plane on the substrate 1. However, the process of epitaxy growth of the hexagonal wurtzite crystal structure at the M-plane or A-plane is not the focus of the present invention, there will no longer be detailed in the present invention.

Because of the electric field induced by both spontaneous polarization and piezoelectric polarization existed in the hexagonal wurtzite crystal structure of group III nitride semiconductor light emitting diode along the C-axis [0001] thereof, the movement of electron-hole can be speeded up through the electric field when the direction from the first electrode metal pad 5 to the second electrode metal pad 6 is the same with that of C-axis [0001] of the hexagonal wurtzite crystal structure. Therefore, the combination efficiency of electron-hole can be increased, the threshold voltage dropped, and the output power improved.

In accordance to the aforesaid, the present invention has following advantages:
1. The direction from the first electrode metal pad to the second electrode metal pad is parallel to that of the electric field induced by both spontaneous polarization and piezoelectric polarization in the hexagonal wurtzite crystal structure, so the probability of electron-hole overlap can be increased as well as the threshold voltage of the light emitting diode device can be dropped to further increase the output power.
2. The layered structure is formed through epitaxy growth of the hexagonal wurtzite crystal structure having a M-plane or a A-plane on the substrate, resulting in the reduction of spontaneous polarization effect. Thus electrons and holes can be more evenly distributed in the light emitting layer and the external quantum efficiency droop can be effectively reduced at higher current densities.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A group III nitride semiconductor light emitting diode, comprising:
a substrate for epitaxy growth of a hexagonal wurtzite crystal structure; and a layered structure formed on the substrate, wherein the layered structure comprises: a n-type semiconductor layer; a light emitting layer on the n-type semiconductor layer; a p-type semiconductor layer on the light emitting layer; a first electrode metal pad on the p-type semiconductor layer; and a second electrode metal pad on the n-type semiconductor layer, wherein the n-type semiconductor layer, the light emitting layer and the p-type semiconductor layer are composed of group III nitrides, and wherein a direction from the first electrode metal pad to the second electrode metal pad is the same with the direction of C-axis [0001] of the hexagonal wurtzite crystal structure.

2. The group III nitride semiconductor light emitting diode as claimed in claim 1, wherein the first electrode metal pad is a p-type electrode; the second electrode metal pad is a n-type electrode.

3. The group III nitride semiconductor light emitting diode as claimed in claim 1, wherein the substrate is formed of sapphire, SiC, Si, GaN, AlN, or ZnO.

4. The group III nitride semiconductor light emitting diode as claimed in claim 1, wherein the layered structure is formed through epitaxy growth of the hexagonal wurtzite crystal structure having a M-plane on the substrate.

5. The group III nitride semiconductor light emitting diode as claimed in claim 1, wherein the layered structure is formed through epitaxy growth of the hexagonal wurtzite crystal structure having an A-plane on the substrate.

6. The group III nitride semiconductor light emitting diode as claimed in claim 1, wherein the group III nitride is selected from at least one of AlN, GaN, InN, AlGaN, ALInN, InGaN, and AlInGaN.
